(19) United States
(12) Patent Application Publication
(10) Pub. No.: US 2018/0138110 A1
(43) Pub. Date: May 17, 2018

(54) Enhanced Adhesion by Nanoparticle Layer Having Randomly Configured Voids

(71) Applicant: TEXAS INSTRUMENTS INCORPORATED, Dallas, TX (US)

(72) Inventor: Benjamin Stassen Cook, Addison, TX (US)

(21) Appl. No.: 15/354,137

(22) Filed: Nov. 17, 2016

(51) Int. Cl. H01L 23/495; H01L 21/48

(52) U.S. Cl. CPC H01L 23/49541; H01L 21/4828; H01L 23/49586

(57) ABSTRACT

The surface of a substrate of a first material is modified by depositing a layer of a solvent paste comprising nanoparticles of a second material that have a size that provides a melting point at a lower temperature than the melting point temperature of the bulk second material, and nanoparticles of a third material that have a size at least as large as the nanoparticle size of the second material and a melting point at a temperature higher than the melting point temperature of the second material. Nanoparticles of the second material have a higher weight percentage than nanoparticles of the third material. The nanoparticles of the second material are sintered together at the melting point temperature of the second material. Voids are created in the layer of second material by removing the nanoparticles of the third material The voids have random distribution and random three-dimensional configurations.

### FIELD

Embodiments of the present invention are related in general to the field of semiconductor devices and more specifically to the structure and fabrication method of multicomponent nanoparticle layers with controlled porosity, applied to packaged semiconductor devices for enhanced adhesion.

### DESCRIPTION OF RELATED ART

Based on their functions, semiconductor packages include a variety of different materials. Metals formed as leadframes and bonds are employed for mechanical stability and electrical and thermal conductance, and insulators, such as polymeric molding compounds, are used for encapsulations and form factors. In the packaging fabrication flow, it is common practice to attach a plurality of semiconductor chips to a strip of leadframes, to connect the chips to their respective leads, and then to encapsulate the assembled chips in packages, which protect the enclosed parts against mechanical damage and environmental influences such as moisture and light while providing trouble-free electrical connections. After the encapsulation step, the package chips are separated from the leadframe strip into discrete units by a trimming and forming step.

A popular encapsulation technique is the transfer molding method. A leadframe strip with the attached and connected chips is placed in a steel mold, which forms a cavity around each assembled chip. A semi-viscous thermoset polymeric compound is pressured through runners across the leadframe strip to enter each cavity through a gate. After filling the cavities, the compound is allowed to harden by polymerization. Finally, in the degating step, the compound in the runner is broken off at each gate from the compound filling the cavity.

To ensure the unity and coherence of the package, the metallic and non-metallic materials are expected to adhere to each other during the lifetime of the product, while tolerating mechanical vibrations, temperature swings, and moisture variations. Failing adhesion allows moisture ingress into the package, causing device failure by electrical leakage and chemical corrosion. It may further lead to failure of the attachment of semiconductor chips to substrates, to breakage of wire bonds and cracking of solder bumps, and to degraded thermal and electrical energy dissipation.

Today's semiconductor technology employs a number of methods to raise the level of adhesion between the diversified materials so that the package passes accelerated tests and use conditions without delamination. Among the efforts are chemically purifying the molding compounds; activating leadframe metal surfaces for instance by plasma just prior to the molding process; and enhancing the affinity of leadframe metals to polymeric compounds by oxidizing the base metal. Furthermore, design features such as indentations, grooves or protrusions, overhangs and other three-dimensional features are added to the leadframe surface for improved interlocking with the package material.

Another example of known technology to increase adhesion between leadframe, chip, and encapsulation compound in semiconductor packages, is the roughening of the whole leadframe surface by chemically etching the leadframe surface after stamping or etching the pattern from a metal sheet. Chemical etching is a subtractive process using an etchant. Chemical etching creates a micro-crystalline metal surface with a roughness on the order of 1 μm or less. To roughen only one surface of the leadframe adds about 10 to 15% cost to the non-roughened leadframe.

Yet another known method to achieve a rough surface is the use of a specialized metal plating bath, such as a nickel plating bath, to deposit a rough metal (such as nickel) layer. This method is an additive process; the created surface roughness is on the order of 1 to 10 μm. Roughening of the leadframe surface may have some unwelcome side effects. General roughening of the surface impacts wire bonding negatively, since vision systems have trouble seeing the roughened surface; the rough surface shortens capillary life; and micro-contaminants on the rough surface degrades bonding consistency. Generally, rough surfaces tend to allow more bleeding when the resin component separates from the bulk of the chip attach compound and spreads over the surface of the chip pad. Resin bleed, in turn, can degrade moisture level sensitivity and interfere with down bonds on the chip pad. Selective roughening technique is sometimes employed, which involves reusable silicone rubber masks or gaskets; consequently, selective roughening is expensive. For example, protective masks to restrict the chemical roughening to the selected leadframe areas add about 35 to 40% cost to the non-roughened leadframe.

The success of all these efforts has been limited, especially because the adhesive effectiveness is diminishing ever more when another downscaling step of device miniaturization is implemented.

### SUMMARY

Investigating details of adhesion and mechanical bonding between bodies of diverse materials such as polymerics and metals, applicant realized that the properties of an additive metallic layer deposited between the bodies can be exploited. When the additive layer is composed of metallic nanoparticles and the layer is sintered after deposition, the nanoparticles contribute to the adhesion both by metal interdiffusion, improved chemical bonding to polymeric compounds, and by porosity. Applicant found that the porosity and also the interdiffusion can be enhanced when the size and chemical nature of the nanoparticles is taken into consideration. The structural nanoparticles of a material have a size small enough to exhibit a lower melting point relative to the melting point of the bulk material, and the sacrificial nanoparticles consist of compounds readily removed by heating or etching after formation of the additive layer.

As an example, the structural nanoparticles may be selected from a group including metals such as copper, gold, silver, aluminum, tin, zinc, and bismuth with a diameter between about 10 nm and 20 nm; other selections include metal oxides such as copper oxide, and ceramics. Metallic nanoparticles in this size range have a depressed melting point about 30% and 40% lower than the regular melting point of bulk metal, and can neck together at temperatures more than 90% lower than the melting temperature of the bulk form of the material.

Sacrificial nanoparticles may be selected from a group including polymers such as solid carbon-based aliphatic and cyclic compounds, metal oxides and generally oxides, and ceramics. The sacrificial nanoparticles are intermixed with the structural nanoparticles in a solvent or dispersant. The disperse system or mixed paste can be applied to a substrate such as a metal leadframe as used in semiconductor technology with a computer-controlled syringe. The method includes inkjet printing, screen printing, gravure printing, dip coating, and spray coating.

A source of energy (thermal, photonic, electromagnetic, chemical) is applied to the disperse system in order to sinter the structural nanoparticles (by necking between the particles) into cluster structures of irregular three-dimensional size and reduced surface, and to cause a diffusion of the structural nanoparticles into the substrate surface (metal interdiffusion). Based on the sacrificial nanoparticle size, weight percent, applied energy, and atmosphere, the sintered nanoparticle layer has nests filled with sacrificial nanoparticles having random three-dimensional configurations and distributions; some nests may resemble spherical caverns with narrow entrances. The dispersant may be removed during the sintering process, and in addition, the melting point of the structural nanoparticles increases gradually to normal.

After cooling, the solidified structural clusters and nests remain while the sacrificial nanoparticles can be removed by heating, etching (vapor phase or liquid phase), or other removal methods, transforming the nests into pores. The pores left behind in the solidified structural layer have a configuration as well as a distribution, which are random in three dimensions.

Thereafter, a semiconductor chip can be assembled on the substrate; further, a package of polymeric compound can be formed to encapsulate the chip and at least portions of the substrate. For example, the compound employed for the package may be as an epoxy-based molding compound to be bonded to the additive metallic layer. Due to the pores, the compound experiences improved mechanical adhesion, as the compound flows into the pores of the nanoparticle adhesion layer, anchoring the package to the additive metallic layer. By tuning the porosity, the mechanical adhesion between bodies of different material can be improved/tuned in a customized manner.

### BRIEF DESCRIPTION OF THE DRAWINGS

FIG. 1 is a diagram summarizing the process flow of creating an additive layer of structural and sacrificial nanoparticles and transforming the layer into a structure having voids of random three-dimensional configurations and distributions according to an embodiment of the invention.

FIG. 2 illustrates the formation of an additive layer of structural and sacrificial nanoparticles according to an embodiment of the invention.

FIG. 3 shows an enlargement of a portion of the syringe with a nozzle in FIG. 2, wherein the syringe is filled with a paste mixed of structural and sacrificial nanoparticles in a solvent according to an embodiment of the invention.

FIG. 4 depicts the additive layer after sintering the structural nanoparticles, while the sacrificial nanoparticles remain in nests of random three-dimensional configurations and distribution in the layer according to an embodiment of the invention.

FIG. 5 illustrates the additive layer of sintered structural nanoparticles after removal of the sacrificial nanoparticles, the layer having voids with random three-dimensional configurations and distributions according to an embodiment of the invention.

FIG. 6 shows the encapsulation of the additive layer by a packaging compound, which fills the voids of the additive layer according to an embodiment of the invention.

FIG. 7 depicts a normalized melting curve of a metal as a function of nanoparticle diameter; T_{M} is the melting temperature of the particle, T_{MB} is the melting temperature of the bulk [after Wickipedia, “Melting Point Depression”].

FIG. 8 illustrates a packaged semiconductor device with leadframe, wherein portions of the leadframe are covered by a nanoparticle layer having randomly configured pores, enhancing the adhesion between the metallic leadframe and the plastic package according to an embodiment of the invention.

### DETAILED DESCRIPTION OF THE PREFERRED EMBODIMENTS

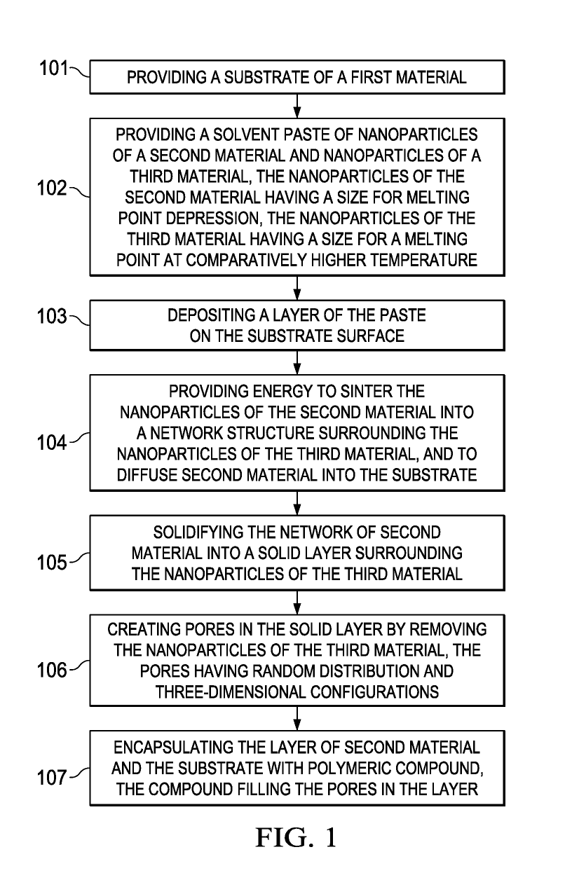

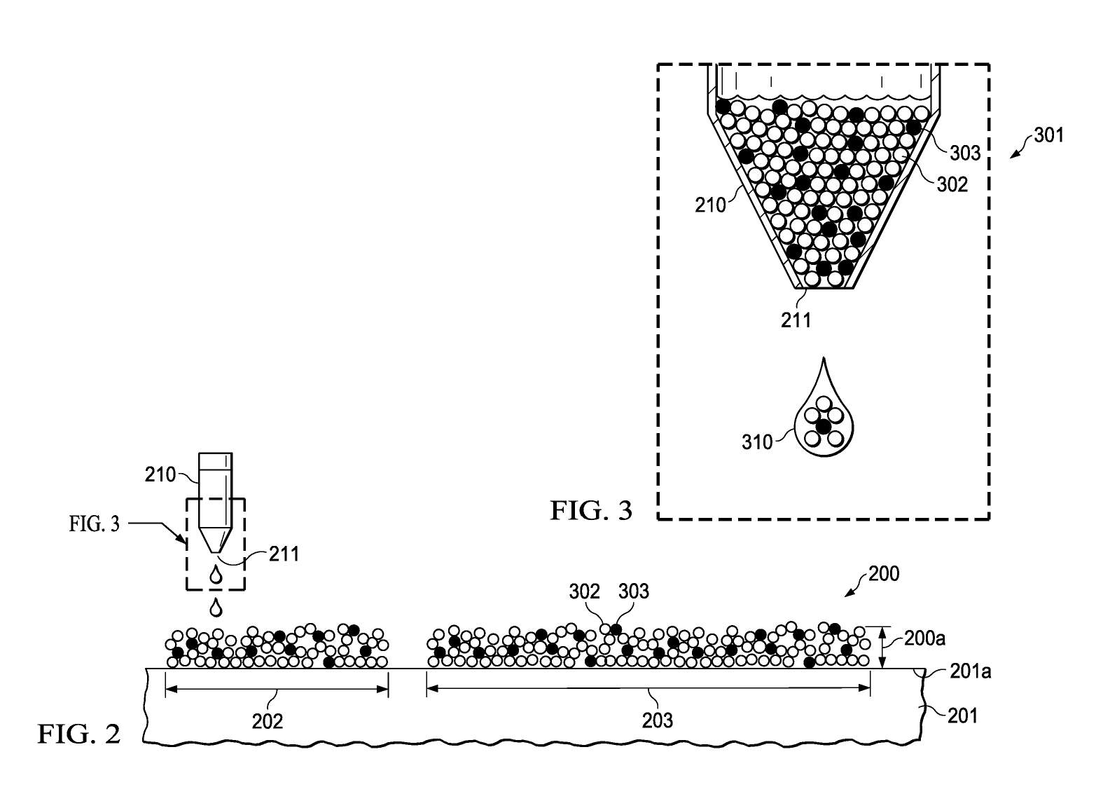

In an embodiment of the invention, a method for enhancing the adhesion and mechanical bonding between objects made of diverse materials such as metals and polymerics is described. The method comprises the formation and anchoring of an additive layer of high surface porosity between the objects. FIG. 1 is a diagram summarizing an embodiment of the invention. An object, onto which the additive layer is constructed, is herein referred to as substrate, while the other object, which needs adhesion improvement to the substrate, is herein referred to as package. As examples, a substrate is denoted 201 in FIG. 2, and a package is denoted 601 in FIG. 6.

An application of the process flow shown in FIG. 1 can be applied to the fabrication technology of semiconductor devices. In semiconductor technology, the substrate typically is either a metallic leadframe or a laminated substrate composed of a plurality of alternating electrically insulating and electrically conductive layers. In process 101 of FIG. 1, a substrate is selected, which is made of a first material and has a surface extending in two dimensions.

When the substrate is a leadframe (FIG. 8), such leadframe is preferably etched or stamped from a thin sheet of base metal such as copper, copper alloy, iron-nickel alloy, aluminum, Kovar™, and others, in a typical thickness range from 120 to 250 μm. As used herein, the term base metal has the connotation of starting material and does not imply a chemical characteristic. Some leadframes may have additional metal layers plated onto the complete or the partial surface areas of the base metal; examples are plated tin, silver, nickel, palladium, and gold layers on copper leadframes.

A leadframe provides a stable support pad (801 in FIG. 8) for firmly positioning the semiconductor chip (810). Further, a leadframe offers a multitude of conductive leads (803) to bring various electrical conductors into close proximity of the chip. Any remaining gap between the tip of the leads and the chip terminals is typically bridged by thin bonding wires (830); alternatively, in flip-chip technology the chip terminals may be connected to the leads by metal bumps. For the leadframe, the desired shape of pad, leads, and other geometrical features are etched or stamped from the original metal sheet.

It is important that the leadframe characteristic facilitate reliable adhesion to an attached chip and to packaging compounds (870 in FIG. 8). Besides chemical affinity between the molding compound and the metal finish of the leadframe, reliable adhesion necessitates leadframe surface roughness, especially in view of the technical trend of shrinking package dimensions, which offers less surface area for adhesion. In addition, the requirement to use lead-free solders pushes the reflow temperature range into the neighborhood of about 260° C., making it more difficult to maintain mold compound adhesion to the leadframes at elevated temperatures.

Referring to the process flow of FIG. 1, in process 102 a solvent paste is provided, which comprises a dispersant or solvent including two different species of nanoparticles. An example of a solvent paste is illustrated in FIG. 3 and designated 301. One kind of nanoparticle, referred to as nanoparticle 302 of a second material, or also as a structural nanoparticle, is made of a second material and quantitatively represented in paste 301 by a first weight percentage. The other kind of nanoparticle, referred to as nanoparticle 303 of a third material or as a sacrificial nanoparticle, is made of a third material and quantitatively represented in paste 301 by a second weight percentage smaller than the first weight percentage.

It should be stressed that the concept of nanoparticles as used herein includes spherical or other three-dimensional clusters composed of atoms or molecules, of inorganic or organic chemical compounds, of one-dimensional wires, of two-dimensional crystals and platelets, and of nanotubes.

The second material may be selected from a group including metals, metal oxides, oxides, and ceramics. The metals may include gold, silver, copper, aluminum, tin, zinc, and bismuth, and the metal oxides may include copper oxide, which, as a mixture of cupric and cuprous oxide with a varying ratio, is known to offer better chemical adhesion to molding compounds than copper. The third material may be selected from a group including polymers, oxides, ceramics, metals, and metal oxides. In the presence second nanoparticles of the second material, the nanoparticles of the third material need to be relatively easy to remove by heat, vapor etching, or liquid phase etching.

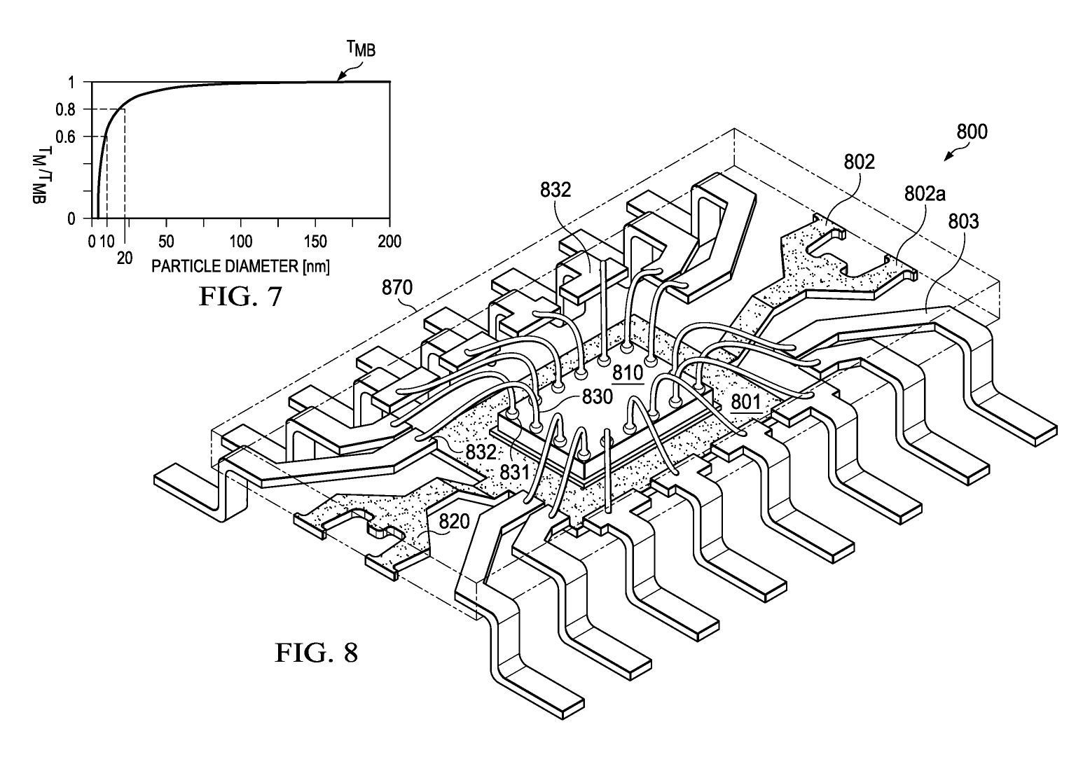

The nanoparticles 302 of the second material have a second size, preferably in the diameter range from 10 nm to 20 nm, in order to offer a depressed melting point at a lower temperature T_{M} compared to the higher melting point at the temperature T_{MB} of bulk second material. While the melting temperature of a bulk material is not dependent on the sample size of the material, studies in recent years have shown that the melting temperature scales with the material dimensions in the range below approximately 50 nm. Nanoscale materials have a much larger surface-to-volume ratio than bulk material, reducing the cohesive energy for atoms located at or near the surface. As the example of FIG. 7 for gold shows, compared to the melting temperature T_{MB} of bulk gold, the melting temperature T_{M} is lowered by approximately 20% for spherical gold particles of about 20 nm diameter, and by approximately 40% for spherical gold particles of about 10 nm diameter.

As used herein, T_{M} refers to the depressed melting temperature of the nanoparticles of the material in comparison to T_{MB}, the melting temperature of the bulk form of the material.

When melting nanoparticles of a volume are sintering together, they form necking connections, where the surfaces of the molten particles exhibit a constricted range resembling a neck between the volumes. Nanoparticles in the size range of <10 nm to 20 nm diameter can neck together at temperatures more than 90% lower than the temperature needed for necking of bulk-size bodies of the material; melting of small particles can happen at temperatures more than 90% lower than the bulk melting temperature. Deviations from a spherical particle shape change the cohesive surface energy and thus the melting point depression. Deviations such as facets, edges, platelets, and wire-shape tend to reduce the melting point depression and bring the melting point closer to the bulk melting point.

The nanoparticles 303 of the third material have a size as least as large as the size of the nanoparticles 302 of the second material. Consequently, the melting temperature of the nanoparticles 303 is higher than the depressed melting temperature of the nanoparticles 302 of the second material.

Referring to the process flow of FIG. 1, during step 103 of the process a layer 200 of the solvent paste 301 is additively deposited on the two-dimensional surface 201a of the substrate 201 shown in FIG. 2. Layer 200 may extend over the available two-dimensional surface area, or it may cover only portions of the surface area by forming islands extending from 0.1 μm to 100 μm dependent on the drop size of the solvent paste. As described above, solvent paste 301 includes a mixture of second nanoparticles 302 and third nanoparticles 303 in a solvent or dispersant; the nanoparticles of the second material have a second size for suppressed melting point of the material, and the nanoparticles of the third material have a third size at least as large as the second size and a melting point at a temperature higher than the suppressed melting point of the nanoparticles of the second material.

Process 103 is depicted in FIG. 2. The equipment preferably includes a computer-controlled inkjet printer with a moving syringe 210 with nozzle 211, from which discrete drops 310 of the paste are released. Automated inkjet printers can be selected from a number of commercially available printers; alternatively, a customized inkjet printer can be designed to work for specific pastes. Any additive method can be used including screen printing, gravure printing, flexographic printing, dip coating, spray coating, and inkjet printing comprising piezoelectric, thermal, acoustic and electrostatic inkjet printing.

As stated, the deposited layer 200 may extend along the lateral dimensions of the whole substrate 201, or may, as depicted in FIG. 2 as exemplary lengths 202 and 203, include islands extending for about 0.1 μm to 100 μm length. In metallic leadframes, layer 200 may cover the whole leadframe surface area of one or more leads, or selected parts such as the chip attach pad. Building up height from compiled drops of repeated runs of syringe 210, layer 200 may preferably have a height 200a between about 100 nm and 500 nm, but may be thinner or considerably thicker.

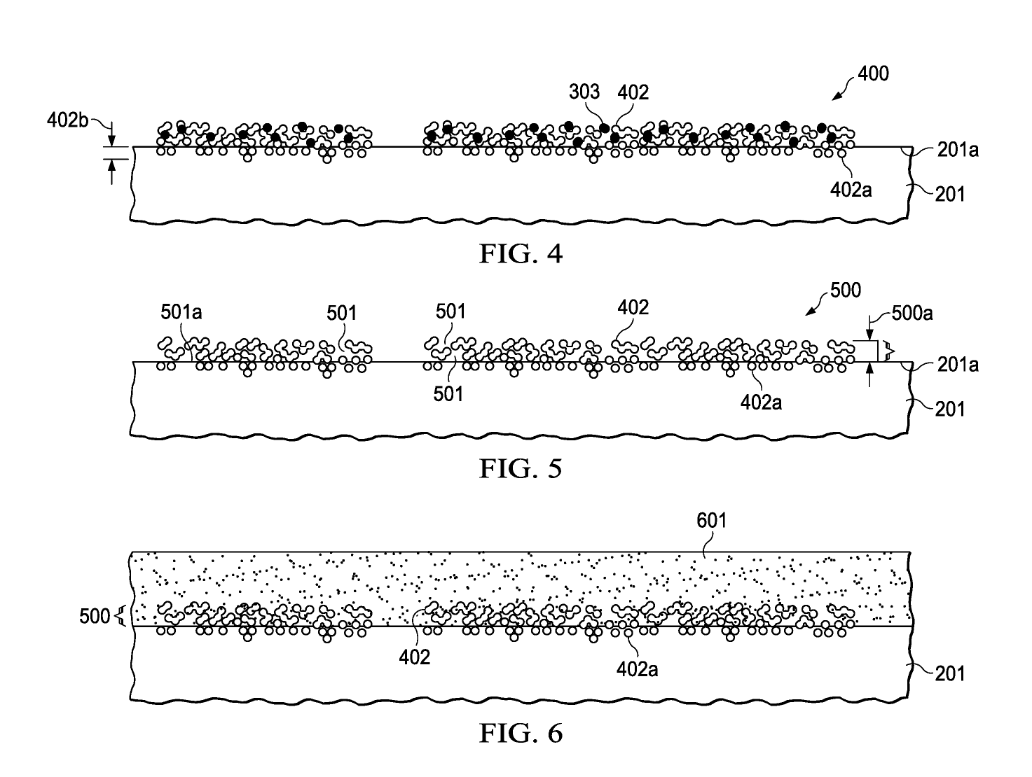

During step 104 of the process shown in FIG. 1, energy is provided to elevate the temperature to the temperature of the depressed melting point of the nanoparticles 302 of the second material. The needed energy may be provided by a plurality of sources: Thermal energy, photonic energy, electromagnetic energy, and chemical energy. At the depressed melting temperature, nanoparticles 302 are sintering together by necking between the particles into a liquid network structure surrounding the third nanoparticles 303. The liquid network structure is indicated in FIG. 4 by sintered particles 402. The sintered nanoparticles 402 surround the unchanged third nanoparticles 303. As FIG. 4 indicates, the unchanged nanoparticles 303 force the sintered nanoparticles 402 to form structures, which are randomly distributed and three-dimensionally randomly configured.

Concurrent with the sintering of the nanoparticles 402 of the second material, some second material is diffusing by atomic interdiffusion into the first material of the region adjoining the surface 201a of substrate 201. In FIG. 4, the second material interdiffused into the region near surface 201a of substrate 201 is designated 402a. The diffusion region (diffusion depth) is designated 402b in FIG. 4. The atomic interdiffusion into the substrate creates an interdiffusion bond, which anchors the layer of sintered second nanoparticles into substrate 201.

During step 105 of the process shown in FIG. 1, the liquid network structure 402 of second material is solidified to create a solid layer 400 of second material 402 surrounding third nanoparticles 303. The increased size of the sintered nanoparticles 302 drives the melting temperature of the sintered entities upwards along the characteristic dependence displayed in FIG. 7. Since the hardened network structure 400 remains at the substrate surface as a solid layer, the nanoparticles 402 of the second material may be referred to as structural nanoparticles.

During step 106 of the process shown in FIG. 1, voids or pores are created in the solid layer 400 of sintered nanoparticles 402 by removing the third nanoparticles 303. The method of removing the third nanoparticles is selected from a group including heating, vapor etching, and liquid phase. Since the nanoparticles 303 can be removed, the nanoparticles of the third material may be referred to as sacrificial nanoparticles. An example of the remaining layer 500 of solid sintered nanoparticles of the second material including the plurality of voids 501 is illustrated in FIG. 5. The thickness of the solid layer 500 is designated 500a.

As FIG. 5 shows, the numerous voids or pores 501 have a random distribution and random three-dimensional configurations. Some of the voids 501 display intricate pathways through the solidified material 402 and some of the three-dimensional voids have spherical shapes with narrow entrances, as exemplified by void 501a in FIG. 5. In order to change the final porosity of layer 500, the weight percentage and the size of the sacrificial nanoparticles can be varied. By changing the porosity, the mechanical adhesion of any material to be adhered to surface 201a can be improved and tuned.

During step 107 of the process shown in FIG. 1, the solid and porous layer 500 of second material and at least portions of the substrate of first material are encapsulated into a package of polymeric compound. The process is illustrated in FIG. 6, wherein the polymeric compound is denoted 601. The preferred method for encapsulation by a polymeric compound is a transfer molding technology using a thermoset epoxy-based molding compound. Since the compound has low viscosity at the elevated temperature during the molding process, the polymeric compound can readily fill the pores 501a in the layer 500 of second material. The filling of the pores by polymeric material takes place for any pores, whether they are arrayed in an orderly pattern or in a random distribution, and whether they are shallow or in a random three-dimensional configuration including pores resembling spherical caverns with narrow entrances.

After the compound has polymerized and cooled down to ambient temperature, the polymeric compound 601 in the package as well as in the pores is hardened. After hardening of the plastic material, the polymeric-filled pores represent a strong anchor of the package in the layer 500. In addition, as mentioned above, layer 500 is anchored in metallic substrate 201 by metal interdiffusion. As an overall result, the porous layer 500 improves the adhesion between the plastic package 601 and the metallic substrate 201. Adhesion improvements of an order of magnitude have been measured.

It is practical to express the strong adhesion of the packaging compound 601 to the substrate metal 201 by the amount of surface porosity of layer 500. A parameter indicating the amount of porosity is a surface area ratio defined as the surface area (three-dimensional) relative to a geometrically flat surface area (two-dimensional). The quantitative parameter values are based on a detailed analysis of the surface contours.

The adhesion of two different material discussed above is, strictly speaking, the mechanical adhesion between bodies made of these materials. It should be stressed that overall adhesion between two different materials can be improved, in addition to the mechanical adhesion, by chemical adhesion. Consequently, the nanoparticles of the second material can be chosen to enhance chemical adhesion. As an example, copper oxide nanoparticles have better chemical bonding to polymeric molding compounds than gold nanoparticles.

Another embodiment of the invention is a device, which includes a substrate with a two-dimensional surface, wherein the substrate is made of a first material. On the two-dimensional surface of the substrate is a solid layer of a second material. In addition, the substrate region adjoining the two-dimensional surface includes an admixture of the second material in the first material. The solid layer of second material includes pores, which have random distribution and random three-dimensional configurations. These three-dimensional configurations may include pores resembling spherical caverns with narrow entrances. The device further includes a package made of polymeric compound. The package is positioned on the solid layer of second material; as a consequence, the polymeric compound fills the pores in the layer of second material and thereby anchors the package in the layer. The package anchored in the solid layer and the solid layer anchored in the substrate results in good adhesion of the package with the substrate.

FIG. 8 illustrates an exemplary embodiment of the enhanced adhesion by a nanoparticle layer with randomly configured pores in an exemplary semiconductor device, which includes a metallic leadframe and a plastic package. The leadframe of the exemplary semiconductor device includes a pad 801 for assembling a semiconductor chip 810, tie bars 802 connecting pad 801 to the sidewall of the package, and a plurality of leads 803. It should be noted that herein the tie bars are referred to as straps. The chip terminals are connected to the leads 803 by bonding wires 830, which commonly include ball bond 831 and stitch bond 832. In the example of FIG. 8, leads 803 are shaped as cantilevered leads; in other embodiments, the leads may have the shape of flat leads as used in Quad Flat No-Lead (QFN) devices or in Small Outline No-Lead (SON) devices. Along their longitudinal extension, straps 802 of the exemplary device in FIG. 8 include bendings and steps, since pad 801 and leads 803 are not in the same plane. In other devices, straps 802 are flat and planar, because pad 801 and leads 803 are in the same plane.

In FIG. 8, the portions of the leadframe which are included in a layer 500 made of nanoparticles and have voids of random distribution and random three-dimensional configurations, are marked by dashing 870. Since the exemplary device 800 includes a package 870 for encapsulating chip 810 and wire bonds 830, the pores of layer 500 are filled by the polymeric compound. Preferably, package 870 is made of a polymeric compound such as an epoxy-based thermoset polymer, formed in a molding process, and hardened by a polymerization process. The adhesion between the polymeric compound of package 870 and the leadframe is improved by the porous layer 500 with pores of random three-dimensional configurations. Other devices may have more and larger areas of the leadframe covered by the porous layer 500.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example in semiconductor technology, the invention applies not only to active semiconductor devices with low and high pin counts, such as transistors and integrated circuits, but also to combinations of active and passive components on a leadframe pad.

As another example, the invention applies not only to silicon-based semiconductor devices, but also to devices using gallium arsenide, gallium nitride, silicon germanium, and any other semiconductor material employed in industry. The invention applies to leadframes with cantilevered leads and to QFN and SON type leadframes.

As another example, the invention applies, in addition to leadframes, to laminated substrates and any other substrate or support structure, which is to be bonded to a non-metallic body.

It is therefore intended that the appended claims encompass any such modifications or embodiments.

1. A device comprising:
a substrate of a first material;
a diffusion region at a surface of the substrate, the diffusion region including an admixture of a second material in the first material;
a sintered structure adjoining the surface of the substrate, the sintered structure including;
sintered nanoparticles of the second material; and a polymeric compound filling voids having random distribution and random three-dimensional configurations within the sintered structure; the nanoparticles of the second material having a first size, a first weight percentage and a first melting point temperature lower than a melting point temperature of the sintered structure; and
the voids resulting from a removal of nanoparticles of a third material from within the sintered structure; the nanoparticles of the third material having a second size at least as large as the first size, a second weight percentage smaller than the first weight percentage, and a second melting point temperature higher than the first melting point temperature.

2. The device of claim 1, wherein some of the voids have a substantially spherical shape and entrances.

3. The device of claim 1, wherein the substrate is a metallic leadframe.

4. The device of claim 3, wherein the metallic leadframe includes a base metal and metal layers plated on the base metal.

5. The device of claim 3, wherein a semiconductor chip is mounted on the metallic leadframe and covered by the polymeric compound.

6. The device of claim 1, wherein the second material is selected from a group including metals, metal oxides, oxides, and ceramics.

7. A method for substrate modification, the method comprising:
providing a substrate of a first material;
additively depositing a layer of a solvent paste on a surface of the substrate, the solvent paste comprising:
nanoparticles of a second material with a first weight percentage, the nanoparticles of the second material having a size that creates a melting point at a lower temperature than a melting point temperature of a bulk second material; and
nanoparticles of a third material with a second weight percentage smaller than the first weight percentage, the nanoparticles of the third material having a size at least as large as the nanoparticle size of the second material and a melting point at a temperature higher than the melting point temperature of the nanoparticles of the second material;
sintering together the nanoparticles of the second material at the melting point temperature of the second material, wherein a sintered structure surrounds the nanoparticles of the third material; and
creating voids in the sintered structure by removing the nanoparticles of the third material;
wherein the voids have random distribution and random three-dimensional configurations.

8. The method of claim 7, wherein the substrate is selected from a group including metallic substrates, metallic leadframes, and laminated substrates including metallic layers alternating with insulating layers.

9. The method of claim 8, wherein the first material is selected from a group including copper, copper alloys, aluminum, aluminum alloys, iron-nickel alloys, and Kovar™.

10. The method of claim 9, wherein the first material includes a plated layer of a metal selected from a group including tin, silver, nickel, palladium, and gold.

11. The method of claim 7, wherein a method of additively depositing is selected from a group including screen printing, flexographic printing, gravure printing, dip coating, spray coating, and inkjet printing comprising piezoelectric, thermal, acoustic, and electrostatic inkjet printing.

12. The method of claim 7, wherein the second material is selected from a group including metals, metal oxides, oxides, and ceramics.

13. The method of claim 12, wherein a size of the nanoparticles of the second material is in the range from about 10 nm to 20 nm.

14. The method of claim 7, wherein the third material is selected from a group including polymers, oxides, ceramics, metals, and metal oxides.

15. The method of claim 7, wherein an energy for sintering the second nanoparticles is selected from a group including thermal energy, photonic energy, electromagnetic energy, and chemical energy.

16. The method of claim 7, wherein a method of removing the third nanoparticles is selected from a group including heating, vapor etching, and liquid phase etching.

17. The method of claim 7, wherein some of the voids have a substantially spherical shape and narrow entrances.

18. A method for enhancing adhesion of packaged semiconductor device % the method comprising:
providing a substrate of a first material;
providing a solvent paste including nanoparticles of a second material with a first weight percentage, and nanoparticles of a third material with a second weight percentage smaller than the first weight percentage;
wherein the nanoparticles of the second material have a size that provides a melting point at a lower temperature than a melting point temperature of a bulk second material, and the nanoparticles of the third material have a size at least as large as the nanoparticle size of the second material and a melting point at a temperature higher than the melting point temperature of the nanoparticles of the second material;
additively depositing a layer of the paste on a surface of the substrate;
providing energy to increase temperature of the second material to a temperature above the melting point of the second material;
sintering together the nanoparticles of the second material into a liquid surrounding the nanoparticles of the third material, and concurrently diffusing second material into the first material of the surface of the substrate;
solidifying the liquid of the second material to create a solid layer of second material surrounding the nanoparticles of the third material;
creating voids in the solid layer of second material by removing the nanoparticles of the third material wherein the voids have random distribution and random three-dimensional configurations;
encapsulating the solid layer of second material and the surface of the substrate in a polymeric compound, wherein the polymeric compound fills the voids in the solid layer of second material.

19. The method of claim 18, wherein the substrate is a metallic leadframe.

20. The method of claim 18, wherein the second material is selected from a group including metals, metal oxides, oxides, and ceramics.

21. The method of claim 20, wherein a size of the nanoparticles of the second material is in the range from about 10 nm to 20 nm.

22. The method of claim 18, wherein the third material is selected from a group including polymers, oxides, ceramics, metals, and metal oxides.

23. The method of claim 18, wherein a method of additively depositing is selected from a group including screen printing, flexographic printing, gravure printing, dip coating, spray coating, and inkjet printing comprising piezoelectric, thermal, acoustic, and electrostatic inkjet printing.

24. The method of claim 18, wherein a method of removing the third nanoparticles is selected from a group including heating, vapor etching, and liquid phase etching.

25. The method of claim 18, further including: before encapsulating, assembling a semiconductor circuit chip on the substrate so that the chip will be positioned inside the polymeric compound after encapsulating.

26. The device of claim 1, wherein the sintered structure consists essentially of: the sintered nanoparticles of the second material; and the polymeric compound filling the voids.
